(19) United States
(12) Patent Application Publication
(10) Pub. No.: US 2022/0182768 A1
(43) Pub. Date: Jun. 9, 2022

(54) MEMS MICROPHONE AND METHOD OF MANUFACTURING THE SAME

(71) Applicant: DB HITEK CO., LTD., Seoul (KR)

(72) Inventor: Min Hyun JUNG, Chungcheongbuk-do (KR)

(21) Appl. No.: 17/544,650

(22) Filed: Dec. 7, 2021

(30) Foreign Application Priority Data
Dec. 7, 2020 (KR) 10-2020-0169491

(51) Int. Cl. H04R 19/04; H04R 31/00

(52) U.S. Cl. CPC H04R 19/04; H04R 2201/003; H04R 31/003

(57) ABSTRACT

A MEMS microphone includes a substrate, a diaphragm disposed over the substrate to cover the cavity, the diaphragm being spaced apart from the substrate, a back plate disposed over the diaphragm and in the vibration area, and the back plate being spaced apart from the diaphragm to form an air gap, an upper insulation layer to cover the back plate, the upper insulation layer being configured to hold the back plate to make the back plate being spaced apart from the diaphragm, a plurality of first acoustic holes penetrating through the back plate and the upper insulation layer, and a plurality of second acoustic holes provided to penetrate through only the upper insulation layer, wherein the second acoustic holes have an area ratio per unit area greater than that of the first acoustic holes.

### CROSS-REFERENCE TO RELATED APPLICATION

This application claims priority to Korean Patent Application No. 10-2020-0169491 filed on Dec. 7, 2020, and all the benefits accruing therefrom under 35 U.S.C. § 119, the contents of which are incorporated by reference in their entirety.

### TECHNICAL FIELD

The present disclosure relates to a Micro Electro Mechanical Systems (MEMS) microphone and a method of manufacturing the MEMS microphone. More particularly, the present disclosure relates the MEMS microphone capable of transforming an acoustic wave into an electric signal using a displacement of a diaphragm which occurs due to an acoustic pressure, and the method of manufacturing such a MEMS microphone.

### BACKGROUND

Generally, a capacitive microphone utilizes a variable capacitance between a pair of electrodes which are facing each other to transmit an acoustic signal. The capacitive microphone may be manufactured by a semiconductor MEMS process such that the capacitive microphone has a MEMS type having an ultra-small size, which is referred as MEMS microphone.

The MEMS microphone may include a substrate having a cavity, a diaphragm provided to be bendable and a back plate provided to face the diaphragm.

In order to apply the MEMS microphone to a mobile device such as a mobile phone, it may be required to improve the signal-to-noise ratio (SNR) characteristics of the MEMS microphone. The SNR characteristics may be improved by adjusting a size and a space of each of acoustic holes penetrating through the back plate and an upper insulation layer of supporting the back plate.

### SUMMARY

The example embodiments of the present invention provide a MEMS microphone capable of improving signal to noise ratio (SNR) characteristics.

The example embodiments of the present invention provide a method of manufacturing a MEMS microphone capable of improving signal to noise ratio (SNR) characteristics.

According to an example embodiment of the present invention, a MEMS microphone includes a substrate including, a vibration area defining a cavity, a supporting area surrounding the vibration area, and a peripheral area surrounding the supporting area, a diaphragm disposed over the substrate to cover the cavity, the diaphragm being spaced apart from the substrate to be configured to sense an acoustic pressure to generate a corresponding displacement, a back plate disposed over the diaphragm and in the vibration area, and the back plate being spaced apart from the diaphragm to form an air gap, an upper insulation layer to cover the back plate, the upper insulation layer being configured to hold the back plate to make the back plate being spaced apart from the diaphragm, a plurality of first acoustic holes penetrating through the back plate and the upper insulation layer, and a plurality of second acoustic holes provided to penetrate through only the upper insulation layer, wherein the second acoustic holes have an area ratio per unit area greater than that of the first acoustic holes.

In an example embodiment, each of the second acoustic holes has a size larger than that of each of the first acoustic holes, and the second acoustic holes are arranged at an interval substantially narrower than that of the first acoustic holes

In an example embodiment, each of the second acoustic holes may have a size larger than that of each of the first acoustic holes, and the second acoustic holes may be arranged at an interval substantially identical to that of the first acoustic holes.

Here, each of the second acoustic holes may have a size different from one another.

In an example embodiment, a size of each of the first acoustic holes may be identical to that of each of the second acoustic holes, and the second acoustic holes may be arranged at an interval substantially narrower than that of the first acoustic holes.

In an example embodiment, the MEMS microphone may further comprises a plurality of chamber portions provided in the supporting area, spaced apart from each other along a circumference of the vibration area, each of the chamber portions having a lower surface in contact with an upper surface of the substrate to support the upper insulation layer from the substrate, wherein the second acoustic holes may be arranged inside of the chamber portions.

In an example embodiment, the MEMS microphone may further comprises a lower insulation layer provided under the upper insulation layer and on the substrate and disposed outside of the chamber portions and an intermediate insulation layer provided between the lower insulation layer and the upper insulation layer and disposed outside of the chamber portions, wherein a plurality of slits is provided between the chamber portions with exposing the upper surface of the substrate and communicating with the air gap, respectively.

In an example embodiment, the MEMS microphone may further comprises a diaphragm pad positioned on the lower insulation layer and electrically connected to the diaphragm, and a back plate pad positioned on the intermediate insulation layer and electrically connected to the back plate, wherein the diaphragm pad and the back plate pad are connected to the diaphragm and the back plate through the slits, respectively.

In an example embodiment, wherein the diaphragm may include a plurality of vent holes penetrating through the diaphragm, and spaced apart from each other along one circumference of the diaphragm.

According to an example embodiment of the present invention, a MEMS microphone may be manufactured by forming an insulation layer on a substrate being divided into a vibration area, a supporting area surrounding the vibration area and a peripheral area surrounding the supporting area, forming a diaphragm in the vibration area and on the lower insulation layer, forming an intermediate insulation layer on the lower insulation layer on which the diaphragm is formed, forming a back plate on the intermediate insulation layer in the vibration area, the back plate facing the diaphragm, forming an upper insulation layer on the intermediate insulation layer for holding the back plate to make the back plate spaced apart from the diaphragm, and patterning the back plate and the upper insulation layer to form first acoustic holes of penetrating through the back plate and the upper insulation layer and second acoustic holes of penetrating only through the upper insulation layer, wherein the second acoustic holes have an area ratio per unit area greater than that of the first acoustic holes.

In an example embodiment, wherein each of the second acoustic holes has a size larger than that of each of the first acoustic holes, and the second acoustic holes are arranged at an interval substantially narrower than that of the first acoustic holes.

In an example embodiment, wherein each of the second acoustic holes has a size larger than that of each of the first acoustic holes, and the second acoustic holes are arranged at an interval substantially identical to that of the first acoustic holes.

Here, each of the second acoustic holes has a size different from one another.

In an example embodiment, a size of each of the first acoustic holes is identical to that of each of the second acoustic holes, and the second acoustic holes are arranged at an interval substantially narrower than that of the first acoustic holes.

In an example embodiment, forming the upper insulation layer includes forming chambers portions spaced apart from each other for supporting the back plate with surrounding the vibration area, and the second acoustic holes are arranged inside of the chamber portions.

In an example embodiment, after forming the first and the second acoustic holes, the substrate may be patterned to forma cavity to partially expose the lower insulation layer in the vibration area, and an etch process may be performed using the cavity and the first and the second acoustic holes with completely removing portions of the lower insulation layer and the intermediate insulation layer in both the vibration area and the supporting area to form an air gap between the diaphragm and the back plate, a plurality of slits communicating with the air gap, disposed between the chamber portions.

Here, forming the diaphragm includes forming a diaphragm pad in the peripheral area, being electrically connected to the diaphragm, and the diaphragm pad is connected to the diaphragm through a space between the chamber portions adjacent to each other.

Further, forming the back plate includes forming a back plate pad connected to the back plate in the peripheral area simultaneously, and the back plate pad is connected to the back plate through a space between the chamber portions adjacent to each other.

In an example embodiment, forming the diaphragm includes forming a plurality of vent holes of penetrating the diaphragm.

Here, the vent holes serve as fluid paths for an etchant for removing the lower insulation layer and the intermediate insulation layer.

According to embodiments of the present invention, a ratio of the second acoustic holes per unit area may be greater than a ratio of the first acoustic holes per unit area. By making the ratio of the first acoustic holes relatively low, an area of the back plate excluding the first acoustic holes may be relatively increased. Accordingly, the signal-to-noise ratio of the MEMS microphone may be improved by increasing the capacitance of the back plate.

In addition, even though the first acoustic holes have relatively low area ratio such that the back plate has increased acoustic resistance, the second acoustic holes may have a relatively high area ratio in the upper insulating layer except for the back plate to reduce the acoustic resistance of the upper insulating layer. Accordingly, the MEMS microphone may keep the acoustic resistance constant.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Exemplary embodiments can be understood in more detail from the following description taken in conjunction with the accompanying drawings, in which:

FIG. 1 is a plan view illustrating a MEMS microphone in accordance with an embodiment of the present invention;

FIG. 2 is a cross sectional view taken along a line I-I′ in FIG. 1;

FIG. 3 is a cross sectional view taken along a line II-II′ in FIG. 1;

FIG. 4 is a cross sectional view taken along a line III-III′ in FIG. 1;

FIG. 5 is a cross sectional view taken along a line IV-IV′ in FIG. 1;

FIG. 6 is a partial plan view illustrating another example of first acoustic holes and second acoustic holes;

FIG. 7 is a partial plan view illustrating still another example of first acoustic holes and second acoustic holes;

FIG. 8 is a flow chart illustrating a method of manufacturing a MEMS microphone in accordance with an embodiment of the present invention; and

FIGS. 9 to 21 are cross sectional views illustrating a method of manufacturing a MEMS microphone in accordance with an embodiment of the present invention.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF EMBODIMENTS

Hereinafter, specific embodiments will be described in more detail with reference to the accompanying drawings. The present invention may, however, be embodied in different forms and should not be construed as limited to the embodiments set forth herein.

As an explicit definition used in this application, when a layer, a film, a region or a plate is referred to as being ‘on’ another one, it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the present invention are not limited to these terms.

Furthermore, and solely for convenience of description, elements may be referred to as “above” or “below” one another. It will be understood that such description refers to the orientation shown in the Figure being described, and that in various uses and alternative embodiments these elements could be rotated or transposed in alternative arrangements and configurations.

In the following description, the technical terms are used only for explaining specific embodiments while not limiting the scope of the present invention. Unless otherwise defined herein, all the terms used herein, which include technical or scientific terms, may have the same meaning that is generally understood by those skilled in the art.

The depicted embodiments are described with reference to schematic diagrams of some embodiments of the present invention. Accordingly, changes in the shapes of the diagrams, for example, changes in manufacturing techniques and/or allowable errors, are sufficiently expected. Accordingly, embodiments of the present invention are not described as being limited to specific shapes of areas described with diagrams and include deviations in the shapes and also the areas described with drawings are entirely schematic and their shapes do not represent accurate shapes and also do not limit the scope of the present invention.

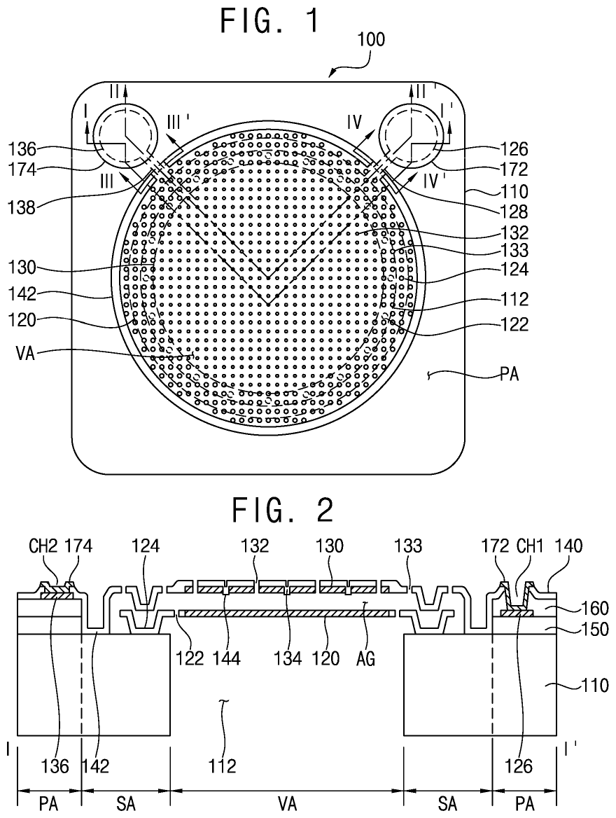

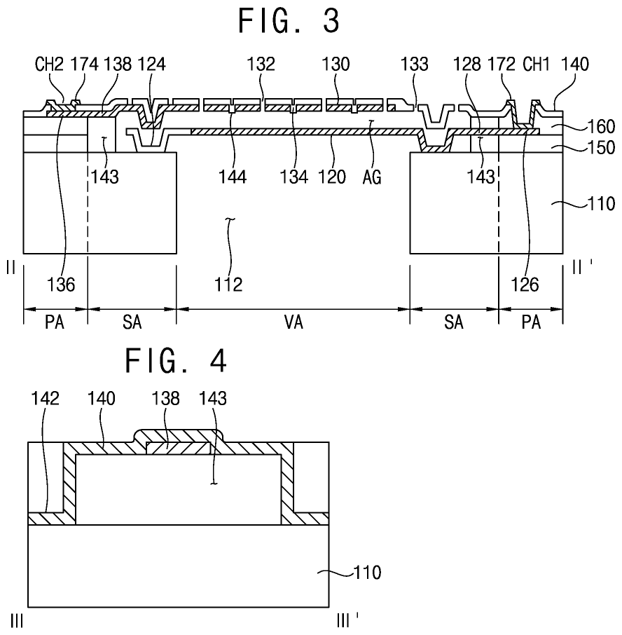

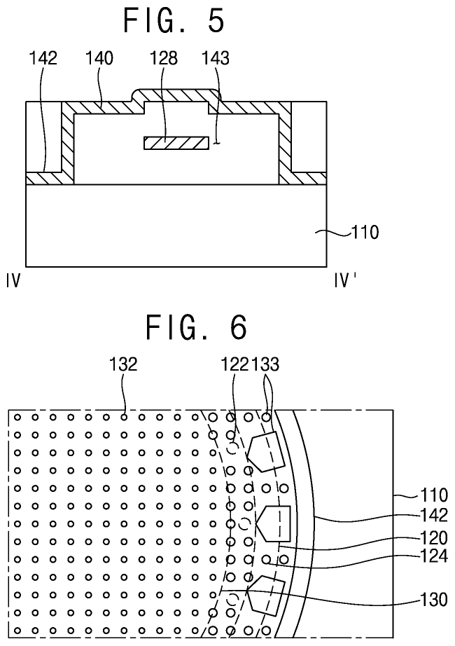

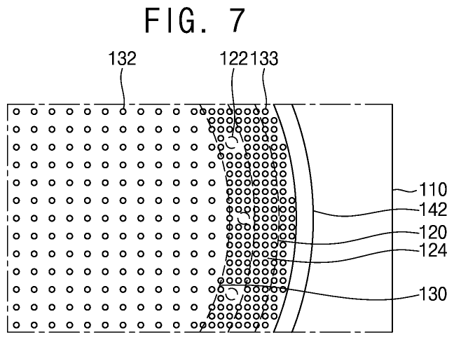

FIG. 1 is a plan view illustrating a MEMS microphone in accordance with an embodiment of the present invention. FIG. 2 is a cross sectional view taken along a line I-I′ in FIG. 1. FIG. 3 is a cross sectional view taken along a line II-II′ in FIG. 1. FIG. 4 is a cross sectional view taken along a line in FIG. 1. FIG. 5 is a cross sectional view taken along a line IV-IV′ in FIG. 1. FIG. 6 is a partial plan view illustrating another example of first acoustic holes and second acoustic holes. FIG. 7 is a partial plan view illustrating still another example of first acoustic holes and second acoustic holes.

Referring to FIGS. 1 to 7, a MEMS microphone 100 is shown that is capable of generating a displacement in response to an acoustic pressure to convert an acoustic signal into an electrical signal and output the electrical signal. The MEMS microphone 100 in accordance with an example embodiment of the present invention includes a substrate 110, a diaphragm 120 and a back plate 130.

The substrate 110 is divided into a vibration area VA, a supporting area SA surrounding the vibration area VA and a peripheral area PA surrounding the supporting area SA. In the vibration area VA, a cavity 112 penetrating through the substrate in a vertical direction is formed. Thus, the cavity 112 may define the vibration area VA.

For example, the cavity 112 may have a substantially circular or ring shape, and may have a size corresponding to the vibration area VA.

The diaphragm 120 may be positioned over the substrate 110. The diaphragm 120 may have a membrane structure to cover the cavity 112. The diaphragm 120 is exposed through the cavity 112. The diaphragm 120 is spaced apart from the substrate 110 in a vertical direction and is configured to be bendable in response to an acoustic pressure.

The diaphragm 120 may have an ion implantation region into which impurities such as type III elements or type V elements are doped. The ion implantation region may correspond to the vibration area VA. The diaphragm 120 may have a substantially circular shape.

In particular, the diaphragm 120 may have an end portion being connected to an anchor 124. The anchor 124 is positioned in the supporting area SA of the substrate 110. The anchor 124 may extend along a circumference of the diaphragm 120. The anchor 124 may have a ring shape and may surround the cavity 112.

The anchor 124 may be disposed in the supporting area SA, and supports the diaphragm 120. The anchor 124 extends from the end portion of the diaphragm 120 toward the substrate 110 to separate the diaphragm 120 from the substrate 110.

For one example, the anchor 124 may have a complete ring shape without an interval. Accordingly, the anchor 124 has a closed structure rather than an open structure. Even when air is provided into the MEMS microphone 100 for performing an air blowing inspection, an air pressure may be incident upon the anchor 124 uniformly in its entirely. Since deformation or damage of the MEMS microphone 100 is prevented, the MEMS microphone 100 may have improved physical properties.

For another example, although not shown, a plurality of anchors 124 may be provided along a circumference of the diaphragm 120 to be spaced apart from each another. Specifically, each of the anchors 124 may have a columnar shape. Each of the anchors 124 may has a vertical section of a “U” shape. An empty space formed between the anchors 130 adjacent to each other may serve as a path through which the acoustic wave flows.

In an example embodiment, the diaphragm 120 may have a plurality of vent holes 122. The vent holes 122 may be arranged along the anchor 124 and may be spaced apart from one another to be arranged in a ring shape.

The vent holes 122 may penetrate through the diaphragm 120 to communicate with the cavity 112. The vent holes 122 may serve as vent channels for the acoustic wave to flow. Further, the vent holes 122 may serve as fluid paths for an etchant to flow while manufacturing the MEMS microphone 110.

The vent holes 122 are positioned in the vibration area VA. Alternatively, the vent holes 122 may be arranged along a boundary between the vibration area VA and the supporting area SA or in the supporting area SA adjacent to the vibration area VA.

The back plate 130 may be positioned over the diaphragm 120. The back plate 130 may be disposed in the vibration area VA. The back plate 130 is spaced apart from the diaphragm 120 and is provided to face the diaphragm 120. Like the diaphragm 120, the back plate 130 may have a circular shape.

In an example embodiment, the MEMS microphone 110 may further include an upper insulation layer 140 and a plurality of chamber portions 142 for supporting the back plate 140 from the substrate 110.

In particular, the upper insulation layer 140 may be disposed over the substrate 110. The upper insulation layer 140 may also cover an upper surface of the back plate 130. The upper insulation layer 140 may hold the back plate 130 to make the back plate 130 spaced apart from the diaphragm 120. Thus, since the back plate 130 is spaced apart from the diaphragm 120, the diaphragm 120 may freely vibrate in response to the acoustic pressure. Further, an air gap AG may be formed between the diaphragm 120 and the back plate 130.

The back plate 130 may include a plurality of first acoustic holes 132 through which the acoustic pressure passes. The first acoustic holes 132 may penetrate through the back plate 130 and the upper insulation layer 140 to communicate with the air gap AG.

A plurality of second acoustic holes 133 may be formed in the supporting area SA, not in the vibration area VA which the back plate 130 is formed. The second acoustic holes 133 may penetrate through the upper insulation layer 140 to communicate with the air gap AG.

Each of the first and second acoustic holes 132 and 133 may have various shapes, such as a circular shape and a polygonal shape, etc.

The second acoustic holes 133 may an area ratio per unit area greater than that of the first acoustic holes 132. The area ratio of the acoustic holes is defined as a total area of the acoustic holes which occupy the back plate 130 per unit area of the back plate 130.

For example, as shown in FIGS. 1 and 6, each of the second acoustic holes 133 may have a size larger than that of each of the first acoustic holes 132. The second acoustic holes 133 are arranged at an interval substantially either narrower than that of the first acoustic holes 132, or identical to that of the first acoustic holes 132. Each of the second acoustic holes 133 may have either a certain size identical to one another or various sizes different from one another.

On the other hand, as shown in FIG. 7, the size of each of the first acoustic holes 132 and the size of the second acoustic holes 133 are identical to one another. Further, the second acoustic holes 133 are arranged at an interval substantially narrower than that of the first acoustic holes 132.

Thus, the first acoustic holes 132 has a relatively low area ratio per unit area whereas the back plate 130 may have a relatively high effective area ratio, excluding the first acoustic holes 132. Accordingly, the MEMS microphone 100 may have improved SNR characteristics by increasing the capacitance value of the back plate 130.

In addition, since the first acoustic holes 132 has relatively low area ratio, the back plate 130 may have a relatively high acoustic resistance in the vibration area VA. However, the second acoustic holes 133 may have a relatively high area ratio to increase the acoustic resistance in the upper insulating layer 140 excluding the back plate 130 in the supporting area SA, such that the upper insulating layer 140 may have reduced acoustic resistance. Thus, the decreased acoustic resistance in the supporting area SA may compensate for the increased acoustic resistance in the vibration area VA. Accordingly, the MEMS microphone 100 may keep the acoustic resistance constant.

The first acoustic holes 132 may be disposed to be alternatively arranged with the vent holes 122 in a vertical direction. That is, the first acoustic holes 132 and the vent holes 122 may not be overlapped with each other in the vertical direction. Accordingly, the acoustic wave may be prevented from being directly transmitted between the vent holes 122 and the first acoustic holes 132. That is, after the acoustic wave passes through the vent holes 122, the acoustic wave may be prevented from being directly transmitted to the first acoustic holes 132. Further, after the acoustic wave passes through the first acoustic holes 132, the acoustic wave may be prevented from being directly transmitted to the vent holes 122.

In an example embodiment, the back plate 130 may have a plurality of dimple holes 134, and the upper insulation layer 140 may have a plurality of dimples 144 positioned to correspond to those of the dimple holes 134. The dimple holes 134 penetrate through the back plate 130, and the dimples 144 are provided at positions where the dimple holes 134 are formed.

The dimples 144 may protrude from a lower surface of the back plate 130 toward the diaphragm 120. Thus, the dimples 144 may prevent the diaphragm 120 from being coupled to the lower surface of the back plate 130.

In particular, the diaphragm 120 may be bent up and down in accordance with the acoustic pressure. A degree of bending of the diaphragm 120 varies according to a magnitude of the acoustic pressure. Even when the diaphragm 120 is severely bent (e.g., so much that the diaphragm 120 contacts the back plate 130), the dimples 144 may separate the diaphragm 120 and the back plate 130 from one another so that the diaphragm 120 may return to an initial position rather than becoming stuck in contact with one another more permanently.

The chamber portions 142 may be positioned in the supporting area SA and adjacent to the boundary between the supporting area SA and the peripheral area PA, and support the upper insulation layer 140 such that the upper insulation layer 140 and the back plate 130 are spaced apart from the diaphragm 120. The chamber portions 142 are formed by bending the upper insulation layer 140 toward the substrate 110. As shown in FIG. 2, lower surfaces of the chamber portions 142 may be disposed in contact with the upper surfaces of the substrate 110.

The chamber portions 142 are spaced outwardly apart from the diaphragm 120 and may be located outside of the anchor 124. The chamber portions 142 may be arranged to have a substantially ring shape, and may be disposed to surround the diaphragm 120.

For example, each of the chamber portions 142 may be provided integrally with the upper insulation layer 140, and may have a ‘U’-shaped longitudinal cross-section.

The chamber portions 142 may be spaced apart from each other. Slits 143 may be provided between the chamber portions 142 adjacent to each other. The slits 143 may expose the upper surface of the substrate 110 and communicate with the air gap AG.

In some embodiments, the MEMS microphone 100 may further include a lower insulation layer 150, a diaphragm pad 126, an intermediate insulation layer 160, a back plate pad 136, a first pad electrode 172 and a second pad electrode 174.

In particular, the lower insulation layer 150 may be formed on the upper surface of the substrate 110 and beneath the upper insulation layer 140. The lower insulation layer 150 may be located in the peripheral area PA and outside of the chamber portions 142.

The diaphragm pad 126 may be formed on the upper face of the lower insulation layer 150. The diaphragm pad 126 may be positioned in the peripheral area PA. The diaphragm pad 126 may be electrically connected to the diaphragm 120. The diaphragm pad 126 may be doped with impurities through ion implantation process.

A first connection portion 128 may connects the anchor 124 to the diaphragm pad 126. In this case, the diaphragm pad 126 may be connected to the diaphragm 120 via the anchor 124 and the first connection portion 128.

The first connection portion 128 may also be doped with impurities. In this case, the first connection portion 128 may connect the diaphragm 120 and the diaphragm pad 126 through any one of the slits 143. Accordingly, the first connection portion 128 may not interfere with the chambers 142.

Meanwhile, when space is formed between the anchors 124, the first connection portion 128 may connect the diaphragm 120 and the diaphragm pad 126 with each other.

The intermediate insulation layer 160 may be formed on the lower insulation layer 150 having the diaphragm pad 126. The intermediate insulation layer 160 is interposed between the lower insulation layer 150 and the upper insulation layer 140, and is located in the peripheral area PA. The intermediate insulation layer 160 may be positioned outside of the chamber portions 142.

In addition, the lower insulation layer 150 and the intermediate insulation layer 160 may be formed using a material different from that of the upper insulation layer 140. For example, the upper insulation layer 140 may include a nitride such as silicon nitride, and the lower insulation layer 150 and the intermediate insulation layer 160 may include an oxide such as silicon oxide.

The back plate pad 136 is positioned in the peripheral area PA and may be provided on the upper surface of the intermediate insulation layer 160. The back plate pad 136 is electrically connected to the back plate 130 and may be doped with impurities through an ion implantation process. Although not specifically illustrated in the drawings, impurities may be doped into both the back plate pad 136 and a second connection portion 138 which connects the back plate pad 136 to the back plate 130. In this case, the second connection portion 138 may connect the back plate 130 to the back plate pad 136 through one of the slits 143. Accordingly, the second connection portion 138 may not interfere with the chamber portions 142.

A first contact hole CH1 is located in the peripheral area PA. The first contact hole CH1 penetrates through the upper insulation layer 140 and the intermediate insulation layer 160 to exposes the diaphragm pad 126.

In addition, a second contact hole CH2 is located in the peripheral area PA. The second contact hole CH2 penetrates through the upper insulation layer 140 to exposes the back plate pad 136.

The first pad electrode 172 may be provided on the diaphragm pad 138 in the peripheral area PA. Accordingly, the first pad electrode 172 may be electrically connected to the diaphragm pad 126.

The second pad electrode 174 may be positioned above the back plate pad 136 in the peripheral area PA and may be electrically connected to the back plate pad 136.

As described above, the MEMS microphone 100 may have the low area ratio per unit area of the first acoustic holes 132 to increase the effective area of the back plate 130 excluding the first acoustic holes 132. Accordingly, the MEMS microphone 100 may have improved SNR characteristics by increasing the capacitance value between the back plate 130 and the diaphragm 120.

In addition, even though the first acoustic holes 132 has relatively low area ratio such that the back plate 130 has increased acoustic resistance, the second acoustic holes 133 may have a relatively high area ratio in the upper insulation layer 140 except for the back plate 130 to reduce the acoustic resistance of the upper insulation layer 140. Accordingly, the MEMS microphone may keep the acoustic resistance constant.

Hereinafter, a method of manufacturing a MEMS microphone will be described in detail with reference to the drawings.

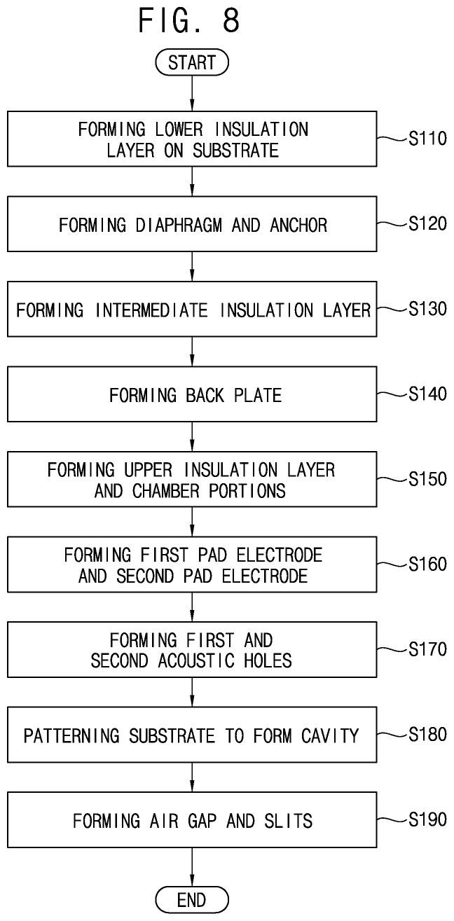

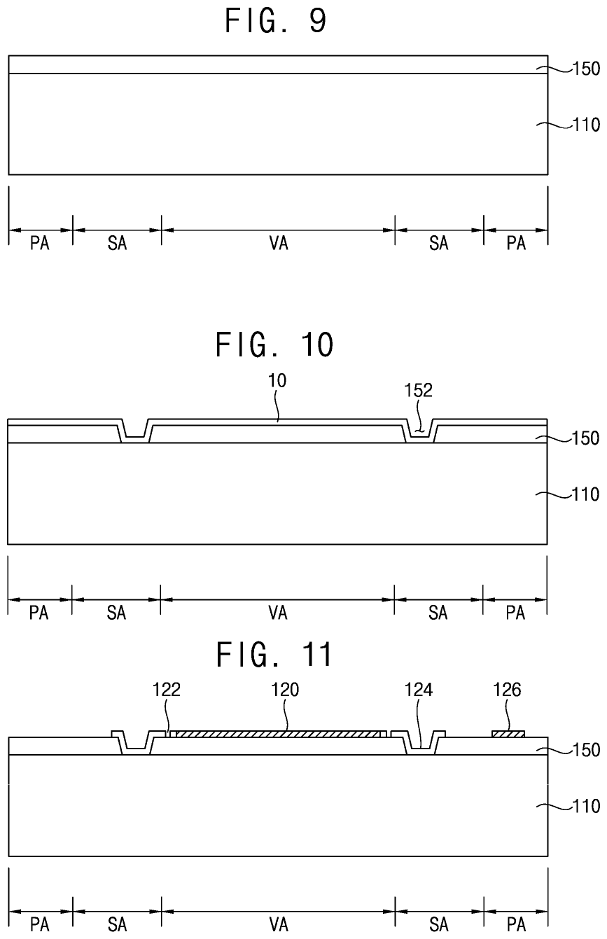

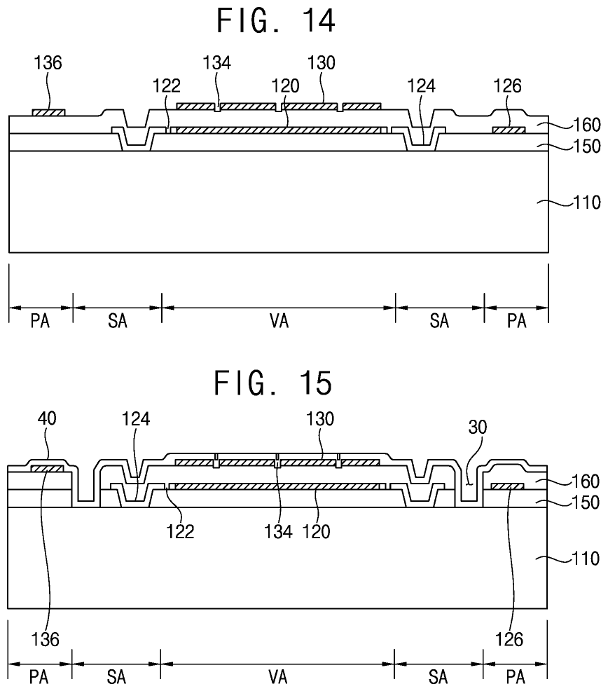

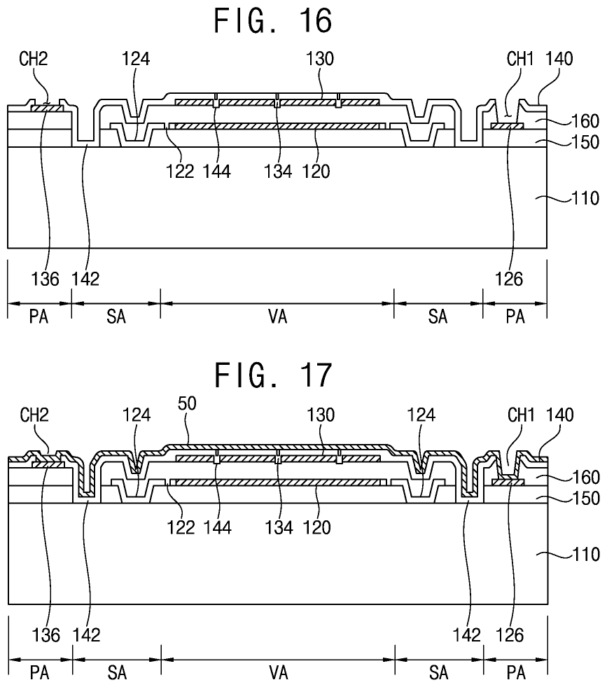

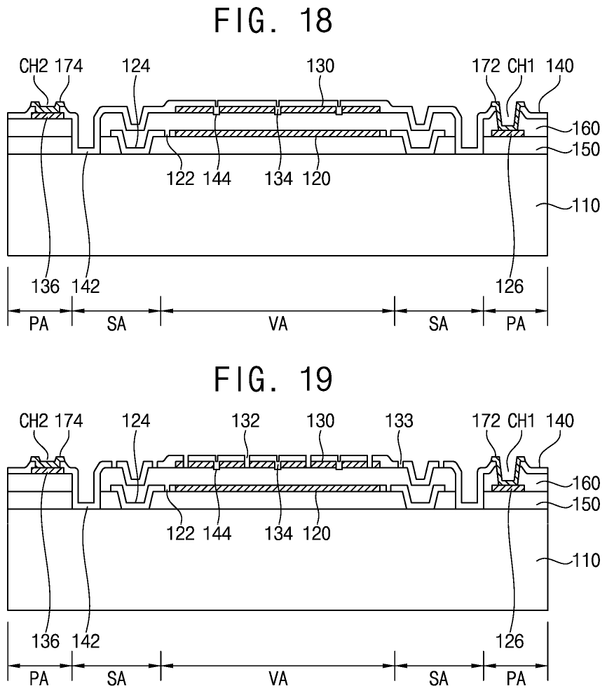

FIG. 8 is a flow chart illustrating a method of manufacturing a MEMS microphone in accordance with an embodiment of the present invention. FIGS. 9 to 21 are cross sectional views illustrating a method of manufacturing a MEMS microphone in accordance with an embodiment of the present invention.

Referring to FIGS. 8 and 9, according to an example embodiment of a method for manufacturing a MEMS microphone, a lower insulation layer 150 is formed on a substrate 110 (at S110).

The lower insulation layer 150 may be formed through a deposition process. The lower insulation layer 150 may be formed using an oxide such as a silicon oxide.

Referring to FIGS. 8, 10 and 11, a diaphragm 120, an anchor 124 and a diaphragm pad 126 are formed on the lower insulation layer 150 (at S120).

The diaphragm 120, the anchor 124 and the diaphragm pad 126 are formed by the subsidiary steps as illustrated in detail as below.

Firstly, the lower insulation layer 150 is patterned by an etching process to form an anchor channel 152 for forming the anchor 124 to partially expose a lower surface of the substrate 110. The anchor channel 152 is formed at a supporting area SA of the substrate 110. For example, the anchor channel 152 has a ring shape of surrounding a vibration area VA.

Then, a first silicon layer 10 is formed on the lower insulation layer 150 having the anchor channel 152. For example, the first silicon layer 10 may be formed using polysilicon.

An ion implanting process is then performed to dope impurities into both the vibration area VA of the first silicon layer 10 and a portion of the first silicon layer 10, corresponding to a position of a diaphragm pad 126.

The first silicon layer 10 is patterned by an etch process to form the diaphragm 120 and the anchor 124, Further, a diaphragm pad 126 may be formed on the lower insulation layer 150 and in a peripheral area PA. A first connection portion 128 may connects the anchor 124 to the diaphragm pad 126. The diaphragm pad 126 may be connected to the diaphragm 120 via the anchor 124 and the first connection portion 128. The first connection portion 128 may also be doped with impurities.

In an example embodiment, the anchor 124 may be formed to have a ring shape along a circumference of the diaphragm 120 to entirely surround the diaphragm 120. Accordingly, the diaphragm pad 126 may be connected to the diaphragm 120 through the anchor 124 and the first connection portion 128.

The anchor 124 has a complete ring shape to have a close structure rather than an open structure. Even when air is provided into the MEMS microphone 100 for performing an air blowing inspection, an air pressure may be uniformly applied to the anchor 124 entirely. Since deformation or damage of the MEMS microphone 100 is prevented, the MEMS microphone 100 may have improved physical properties.

Alternatively, a plurality of anchors 124 is arranged to be spaced apart from each other along the circumference of the diaphragm 120. Further slits may be formed between the anchors adjacent to each other. The slit may serve as a fluid pathway for etchant for removing a portion of an intermediate insulation layer 160, disposed between the diaphragm 120 and the back plate 130.

When the diaphragm 120, the anchor 124 and the diaphragm pad 126 are formed, a plurality of vent holes 122 may also be formed by penetrating through the diaphragm 120. The vent holes 122 are located in the vibration area VA. The vent holes 122 are spaced apart from each other along the anchor 124 and may be arranged to have a ring shape.

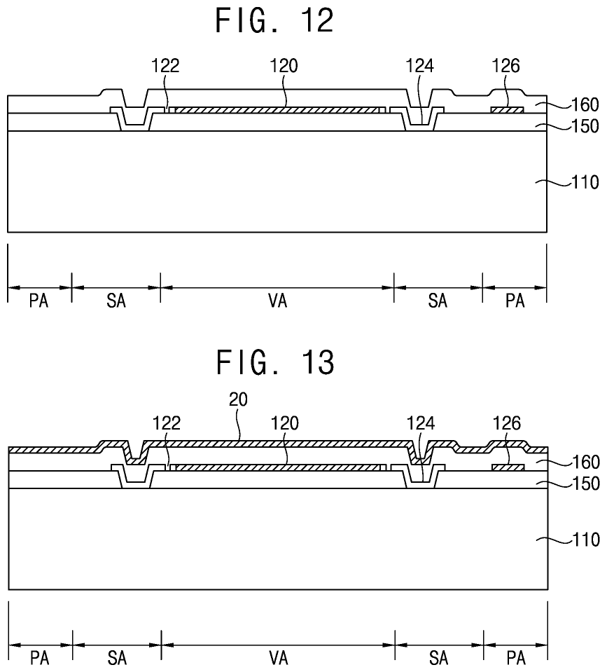

Referring to FIGS. 8 and 12, the intermediate insulation layer 160 is formed on the lower insulation layer 150 on which the diaphragm 120, the vent holes 122, the anchor 124 and the diaphragm pad 126 are formed (at S130).

The intermediate insulation layer 160 may be formed by a deposition process. The intermediate insulation layer 160 may be formed using a material identical to that of the lower insulation layer 150. For example, the intermediate insulation layer 160 is formed using an oxide such as silicon oxide or tetraethyl orthosilicate (TEOS).

The intermediate insulation layer 160 may fill the vent holes 122. Accordingly, the vent holes 122 may be filled with the oxide.

FIGS. 8, 13 and 14, a back plate 130 and a back plate pad 136 are formed on the intermediate insulation layer 160 (at S140).

First, a second silicon layer 20 is deposited on an upper surface of the intermediate insulation layer 160 and then impurities are doped into the second silicon layer 20 through an ion implantation process. For example, the second silicon layer 20 may be made of polysilicon.

The second silicon layer 20 is patterned to form dimple holes 134 for forming dimples 144(refer to FIG. 2). The dimple holes 134 may be formed in the vibration area VA. Specifically, the dimple holes 114 may be provided in a region where the back plate 130 is to be formed. A portion of the intermediate insulation layer 160 corresponding to the dimple hole 134 may be partially etched so that the dimples 144 protrude from a lower surface of the back plate 130 downwardly.

Next, the second silicon layer 20 is patterned to form the back plate 130 and the back plate pad 136. The back plate 130 may be formed in the vibration area VA, and the back plate pad 136 may be formed in the peripheral area PA. In this case, a second connection portion 138 may connect the back plate 130 and the back plate pad 136 to each other (see FIG. 1).

Referring to FIGS. 8, 15 and 16, an upper insulation layer 140 and chamber portions 142 are formed on the intermediate insulation layer 160 on which the back plate 130 and the back plate pad 136 are formed (at S150).

Specifically, the intermediate insulation layer 160 and the lower insulation layer 150 are patterned through an etching process to form chamber channels 30 for forming chamber portions 142 (see FIG. 2) in the supporting area SA. The substrate 110 may be partially exposed through the chamber channels 30. Although not specifically illustrated in the drawings, the chamber channels 30 may be spaced apart from each other, and the chamber channels 30 are arranged to have a substantially ring shape to surround the diaphragm 120. Also, the first connection porting 128 and the second connection portion 138 may be positioned between the chamber channels 30.

After depositing an insulation layer 40 on the intermediate insulation layer 160 on which the chamber channels 30 are formed, the insulation layer 40 is patterned to form the upper insulation layer 140 and the chamber portions 142. The chamber portions 142 may be spaced apart from each other and may be arranged to have a substantially ring shape.

Further, the dimples 144 are formed in the dimple holes 134 while depositing the insulation layer 40 on the intermediate insulation layer 160.

By patterning the insulation layer 40, a second contact hole CH2 is formed in the peripheral area PA to expose the back plate pad 136. Then, portions of the insulation layer 40 and the intermediate insulation layer 160, which face the upper surface of the diaphragm pad 126, are removed to form the first contact hole CH1. The diaphragm pad 126 is exposed through the first contact hole CH1.

The upper insulation layer 140 may be made of a material different from those of the lower insulation layer 150 and the intermediate insulation layer 160. For example, the upper insulation layer 140 may be made of a nitride such as silicon nitride, and the lower insulation layer 150 and the intermediate insulation layer 160 may be made of the oxide.

FIGS. 8, 17 and 18, a first pad electrode 172 and a second pad electrode 174 are formed in the first contact hole CH1 and the second contact holes CH2 in the peripheral area PA (at S160).

Specifically, a thin layer 50 is deposited on the upper insulation layer 140 in which the first contact hole CH1 and the second contact holes CH2 are formed. Here, the thin layer 50 may be made of a conductive metal material.

The thin layer 50 is patterned to form the first pad electrode 172 and the second pad electrode 174. In this case, the first pad electrode 172 may be formed on the diaphragm pad 126, and the second pad electrode 174 may be formed on the back plate pad 136.

Referring to FIGS. 8 and 19, the upper insulation layer 140 and the back plate 130 are patterned to form first acoustic holes 132 and second acoustic holes 133 (at S170).

The first acoustic holes 132 may be formed by penetrating through both the upper insulation layer 140 and the back plate 130 in the vibration area VA. Further, in the supporting area SA, the second acoustic holes 133 may be formed to penetrate through only the upper insulation layer 140 additionally. Each of the first and second acoustic holes 132 and 133 may have various shapes, such as a circular shape and a polygonal shape, etc.

The second acoustic holes 133 may an area ratio per unit area greater than that of the first acoustic holes 132.

For example, each of the second acoustic holes 133 may have a size larger than that of each of the first acoustic holes 132. The second acoustic holes 133 are arranged at an interval substantially either narrower than that of the first acoustic holes 132, or identical to that of the first acoustic holes 132. Each of the second acoustic holes 133 may have either a certain size identical to one another or various sizes different from one another.

On the other hand, the size of each of the first acoustic holes 132 and the size of the second acoustic holes 133 are identical to one another. Further, the second acoustic holes 133 are arranged at an interval substantially narrower than that of the first acoustic holes 132.

Thus, the first acoustic holes 132 has a relatively low area ratio per unit area, whereas the back plate 130 may have a relatively high area ratio of the back plate 130, excluding the first acoustic holes 132. Accordingly, the MEMS microphone 100 may have improved SNR characteristics by increasing the capacitance value of the back plate 130.

In addition, since the first acoustic holes 132 has relatively low area ratio, the back plate 130 may have a relatively high acoustic resistance in the vibration area VA. However, the second acoustic holes 133 may have a relatively high area ratio to increase the acoustic resistance in the upper insulating layer 140 excluding the back plate 130 in the supporting area SA, such that the upper insulating layer 140 may have reduced acoustic resistance. Thus, the decreased acoustic resistance in the supporting area SA may compensate for the increased acoustic resistance in the vibration area VA. Accordingly, the MEMS microphone 100 may keep the acoustic resistance constant.

In an example embodiment, the first acoustic holes 132 may be disposed to be alternatively arranged with the vent holes 122. That is, the first acoustic holes 132 and the vent holes 122 may not be vertically overlapped with one another in a vertical direction. Accordingly, the acoustic wave may be prevented from being directly transmitted between the vent holes 122 and the first acoustic holes 132. That is, after the acoustic wave passes through the vent holes 122, the acoustic wave may be prevented from being directly transmitted to the first acoustic holes 132. Further, after the acoustic wave passes through the first acoustic holes 132, the acoustic wave may be prevented from being directly transmitted to the vent holes 122.

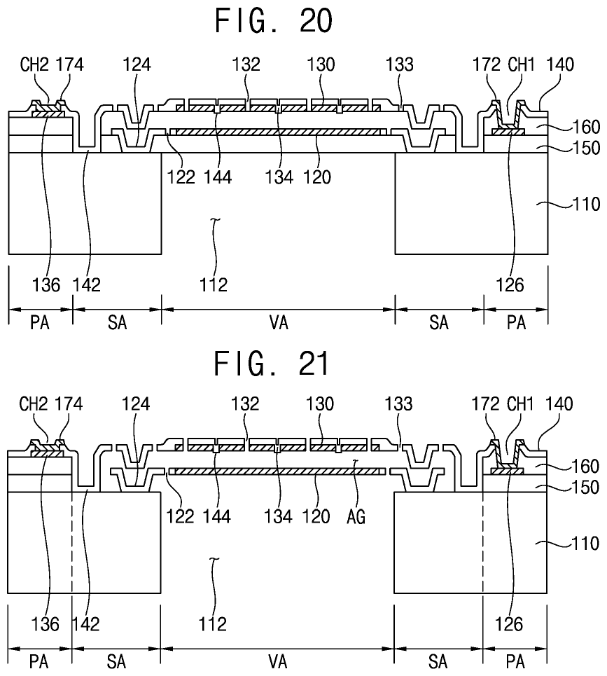

FIGS. 8 and 20, after the first acoustic holes 132 and second acoustic holes 146 are formed, the substrate 110 is patterned to form a cavity 112 in the vibration area VA. (at S180).

The lower insulation layer 150 is partially exposed through the cavity 112.

FIGS. 8 and 21, through an etching process using the cavity 112, the first acoustic holes 132, the second acoustic holes 146 and the vent holes 122, the lower insulation layer 150 and the intermediate insulation layer 160 are removed completely from both the vibration area VA and the supporting area SA, and partially from the peripheral area PA to form an air gap AG between the diaphragm 120 and the back plate 130, a plurality of slits 143 between the chamber portions 142 adjacent to each other, communicating with the air gap AG, and spaces SP outside of the chamber portions 142, communicating with the slits 142, respectively (at S190).

Specifically, the cavity 112, the first acoustic holes 132, the second acoustic holes 146 and the vent holes 122 may be provided as fluid paths of the etchant for removing the lower insulation layer 150 and the intermediate insulation layer 160.

Meanwhile, the anchor 124 and the chamber portions 142 serve to limit the flow area of the etchant.

For example, hydrogen fluoride vapor (HF vapor) may be used as the etchant for removing the intermediate insulation layer 160 and the lower insulation layer 150.

The lower insulation layer 150 and the intermediate insulation layer 160 from the vibration area VA and the support area SA are entirely removed to expose the diaphragm 120 through the cavity 112, and the air gap AG between the diaphragm 120 and the back plate 130, and the slits 143 between the chamber portions 142 adjacent to each other.

Since the first connection portion 128 and the second connection portion 138 communicate with the slits 143, the first connection portion 128 and the second connection portion 138 may not interfere with the chamber portions 142 (see FIGS. 4 and 5).

According to example embodiment, the first acoustic holes 132 has a relatively low area ratio per unit area, whereas the back plate 130 may have a relatively high effective area ratio of the back plate 130, excluding the first acoustic holes 132. Accordingly, the MEMS microphone 100 may have improved SNR characteristics by increasing the capacitance value of the back plate 130.

In addition, since the first acoustic holes 132 has relatively low area ratio, the back plate 130 may have a relatively high acoustic resistance in the vibration area VA. However, the second acoustic holes 133 may have a relatively high area ratio to increase the acoustic resistance in the upper insulating layer 140 excluding the back plate 130 in the supporting area SA, such that the upper insulating layer 140 may have reduced acoustic resistance. Thus, the decreased acoustic resistance in the supporting area SA may compensate for the increased acoustic resistance in the vibration area VA. Accordingly, the MEMS microphone 100 may keep the acoustic resistance constant.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A MEMS microphone comprising:
a substrate including:
a vibration area defining a cavity,
a supporting area surrounding the vibration area, and
a peripheral area surrounding the supporting area;
a diaphragm disposed over the substrate to cover the cavity, the diaphragm being spaced apart from the substrate to be configured to sense an acoustic pressure to generate a corresponding displacement;
a back plate disposed over the diaphragm and in the vibration area, and the back plate being spaced apart from the diaphragm to form an air gap;
an upper insulation layer to cover the back plate, the upper insulation layer being configured to hold the back plate to make the back plate being spaced apart from the diaphragm;
a plurality of first acoustic holes penetrating through the back plate and the upper insulation layer; and
a plurality of second acoustic holes provided to penetrate through only the upper insulation layer,
wherein the second acoustic holes have an area ratio per unit area greater than that of the first acoustic holes.

2. The MEMS microphone of claim 1, wherein each of the second acoustic holes has a size larger than that of each of the first acoustic holes, and the second acoustic holes are arranged more densely than that of the first acoustic holes.

3. The MEMS microphone of claim 1, wherein each of the second acoustic holes has a size larger than that of each of the first acoustic holes, and the second acoustic holes are arranged at a substantially identical interval to that of the first acoustic holes.

4. The MEMS microphone of claim 2, wherein each of the second acoustic holes has a size different from one another.

5. The MEMS microphone of claim 1, wherein a size of each of the first acoustic holes is identical to that of each of the second acoustic holes, and the second acoustic holes are arranged at an interval substantially narrower than that of the first acoustic holes.

6. The MEMS microphone of claim 1, further comprising a plurality of chamber portions provided in the supporting area, spaced apart from each other along a circumference of the vibration area, each of the chamber portions having a lower surface in contact with an upper surface of the substrate to support the upper insulation layer from the substrate,
wherein the second acoustic holes are arranged inside of the chamber portions.

7. The MEMS microphone of claim 6, further comprising:
a lower insulation layer provided under the upper insulation layer and on the substrate and disposed outside of the chamber portions; and
an intermediate insulation layer provided between the lower insulation layer and the upper insulation layer and disposed outside of the chamber portions,
wherein a plurality of slits is provided between the chamber portions with exposing the upper surface of the substrate and communicating with the air gap, respectively.

8. The MEMS microphone of claim 7, further comprising:
a diaphragm pad positioned on the lower insulation layer and electrically connected to the diaphragm; and
a back plate pad positioned on the intermediate insulation layer and electrically connected to the back plate,
wherein the diaphragm pad and the back plate pad are connected to the diaphragm and the back plate through the slits, respectively.

9. The MEMS microphone of claim 1, wherein the diaphragm includes a plurality of vent holes penetrating through the diaphragm, and spaced apart from each other along one circumference of the diaphragm.

10. A method of manufacturing a MEMS microphone comprising:
forming an insulation layer on a substrate being divided into a vibration area, a supporting area surrounding the vibration area and a peripheral area surrounding the supporting area;
forming a diaphragm in the vibration area and on the lower insulation layer;
forming an intermediate insulation layer on the lower insulation layer on which the diaphragm is formed;
forming a back plate on the intermediate insulation layer in the vibration area, the back plate facing the diaphragm;
forming an upper insulation layer on the intermediate insulation layer for holding the back plate to make the back plate spaced apart from the diaphragm; and
patterning the back plate and the upper insulation layer to form first acoustic holes of penetrating through the back plate and the upper insulation layer and second acoustic holes of penetrating only through the upper insulation layer,
wherein the second acoustic holes have an area ratio per unit area greater than that of the first acoustic holes.

11. The method of claim 10, wherein each of the second acoustic holes has a size larger than that of each of the first acoustic holes, and the second acoustic holes are arranged at an interval substantially narrower than that of the first acoustic holes.

12. The method of claim 10, wherein each of the second acoustic holes has a size larger than that of each of the first acoustic holes, and the second acoustic holes are arranged at an interval substantially identical to that of the first acoustic holes.

13. The method of claim 11, wherein each of the second acoustic holes has a size different from one another.

14. The method of claim 10, wherein a size of each of the first acoustic holes is identical to that of each of the second acoustic holes, and the second acoustic holes are arranged at an interval substantially narrower than that of the first acoustic holes.

15. The method of claim 10, wherein forming the upper insulation layer includes forming chambers portions spaced apart from each other for supporting the back plate with surrounding the vibration area, and the second acoustic holes are arranged inside of the chamber portions.

16. The method of claim 10, further comprising:
after forming the first and the second acoustic holes,
patterning the substrate to forma cavity to partially expose the lower insulation layer in the vibration area; and
performing an etch process using the cavity and the first and the second acoustic holes with completely removing portions of the lower insulation layer and the intermediate insulation layer in both the vibration area and the supporting area to form an air gap between the diaphragm and the back plate, a plurality of slits communicating with the air gap, disposed between the chamber portions.

17. The method of claim 16, wherein forming the diaphragm includes forming a diaphragm pad in the peripheral area, being electrically connected to the diaphragm, and the diaphragm pad is connected to the diaphragm through a space between the chamber portions adjacent to each other.

18. The method of claim 16, wherein forming the back plate includes forming a back plate pad connected to the back plate in the peripheral area simultaneously, and the back plate pad is connected to the back plate through a space between the chamber portions adjacent to each other.

19. The method of claim 10, wherein forming the diaphragm includes forming a plurality of vent holes of penetrating the diaphragm.

20. The method of claim 19, wherein the vent holes serve as fluid paths for an etchant for removing the lower insulation layer and the intermediate insulation layer.
